(19) United States
(12) Patent Application Publication
(10) Pub. No.: US 2008/0017970 A1
(43) Pub. Date: Jan. 24, 2008

(54) Brick type stackable semiconductor package

(75) Inventor: Hong-Chi Yu, Kaohsiung (TW)

Correspondence Address: TROXELL LAW OFFICE PLLC, SUITE 1404, 5205 LEESBURG PIKE, FALLS CHURCH, VA, 22041, US

(73) Assignee: Walton Advanced Engineering, Inc.

(21) Appl. No.: 11/727,201

(22) Filed: Mar. 23, 2007

(30) Foreign Application Priority Data
Mar. 30, 2006 (CN) 095111127

(51) Int. Cl. H01L 23/48

(52) U.S. Cl. 257/693; 257/E23.01

(57) ABSTRACT

A brick-type stackable semiconductor package primarily comprises a substrate, at least a memory chip and an encapsulant. The memory chip is disposed on an inner surface of the substrate and is encapsulated by an encapsulant shaped like a brick. A plurality of outer pads and a plurality of transfer pads are formed on an outer surface of the substrate where the transfer pads and the electrically corresponding outer pads are inversely designed in pad locations so that the brick-type semiconductor package can inversely and horizontally stacked in stagger with another brick-type semiconductor package to increase memory capacities.

### FIELD OF THE INVENTION

The present invention relates to a semiconductor package with memory chips on a single side of a substrate, especially, to a brick-type stackable semiconductor package for POP (Package-On-Package) module.

### BACKGROUND OF THE INVENTION

In a conventional Package-On-Package module, a plurality of conductive pads are disposed on the top surface and on the bottom surface of a substrate or a chip carrier where some of the conductive pads on the top surface are electrically connected to the conductive pads on the bottom surface in each package so that a plurality of packages can be vertically stacked. These vertically stacked packages are called “3D packages” as revealed in Taiwan R.O.C. Patent No. 1240394 and 1245385, entitled “Semiconductor package for 3D package” and entitled “Stackable BGA package for multi chip module”. Even a plurality of vertical stacked packages can be expanded according to the variations of functions, however, the overall thickness of the POP stacked module are different and can not easily meet lighter, thinner, shorter, and smaller requirements for the hand-held electronic devices, such as plug-in type memory modules.

### SUMMARY OF THE INVENTION

The main purpose of the present invention is to provide a brick-type semiconductor package including a substrate having an outer surface without encapsulated by an encapsulant. A plurality of outer pads and a plurality of transfer pads are formed on the outer surface where the transfer pads and the electrically corresponding outer pads are inversely designed in pad locations so that the brick-type semiconductor package can inversely and horizontally stacked in stagger with another brick-type semiconductor package. Accordingly, a plurality of brick-type semiconductor packages can be horizontally expanded to increase memory capacity within in a limited height.

According to the present invention, a brick-type semiconductor package primarily includes a substrate, at least a memory chip, and an encapsulant where the substrate has an inner surface and an outer surface. A plurality of outer pads and a plurality of transfer pads are formed on the outer surface. The memory chip is disposed on the inner surface and is electrically connected to the outer pads. The encapsulant is formed on the inner surface of the substrate to encapsulate the memory chip and shaped like a brick where the transfer pads and the electrically corresponding outer pads are inversely designed in pad locations so that the brick-type semiconductor package can inversely and horizontally stacked in stagger with another brick-type semiconductor package.

### DESCRIPTION OF THE DRAWINGS

FIG. 1 shows a view of an outer surface of a substrate of a brick-type semiconductor package according to the first embodiment of the present invention.

FIG. 2 shows a cross-sectional view of the brick-type semiconductor package according to the first embodiment of the present invention.

FIG. 3 shows a cross-sectional view of a plurality of brick-type semiconductor packages inversely and horizontally stacked in stagger according to the first embodiment of the present invention.

FIG. 4 shows a cross-sectional view of another brick-type semiconductor package according to the second embodiment of the present invention.

### DETAIL DESCRIPTION OF THE INVENTION

Please refer to the attached drawings, the present invention will be described by means of embodiment(s) below.

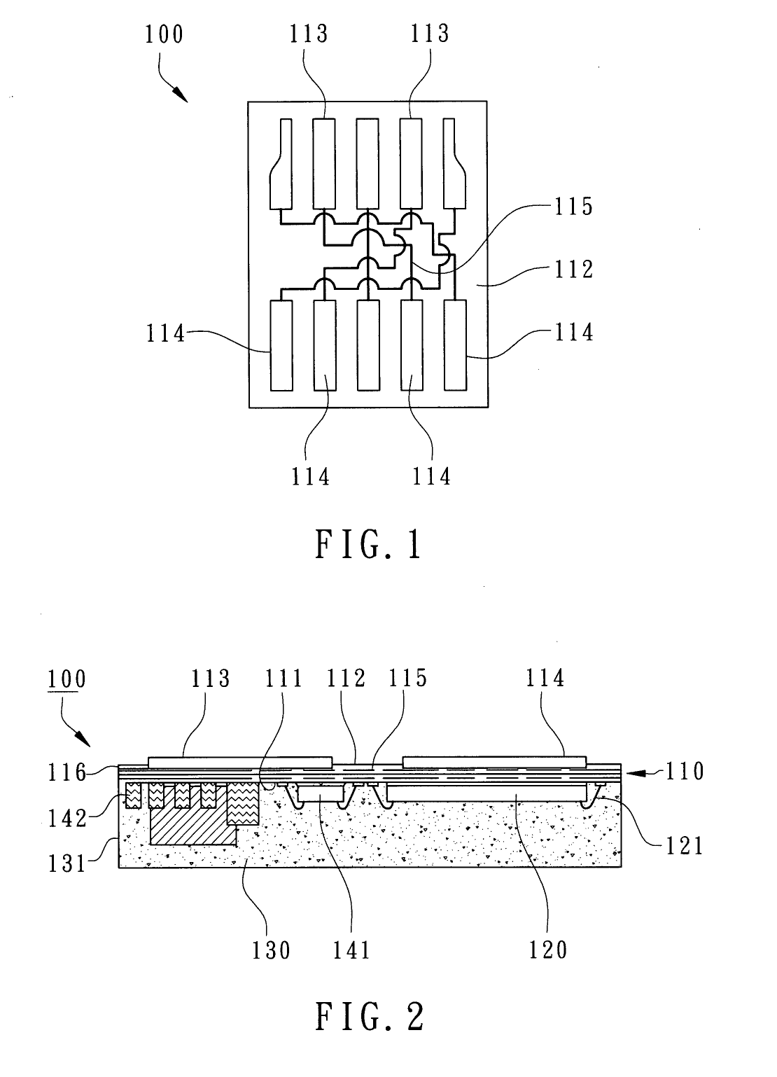

According to the first embodiment of the present invention, as shown in FIG. 1 and FIG. 2, a brick-type semiconductor package 100 primarily comprises a substrate 110, at least a memory chip 120 and an encapsulant 130 where the substrate 110 acts as a chip carrier and a signal transferring interface. The substrate 110 has an inner surface 111 and an outer surface 112 with internal traces 115 formed inside the substrate 110. The inner surface 111 is the encapsulated surface of the substrate 110 and the outer surface 112 is exposed from the encapsulant 130 of the brick-type semiconductor package 100 and is corresponding to the inner surface 111. A plurality of outer pads 113 and a plurality of transfer pads 114 are both formed on the outer surface 112 where at least parts of the transfer pads 114 are electrically connected to parts of the outer pads 113 through the internal traces 115 of the substrate 110. The outer pads 113 and the transfer pads 114 may be gold fingers or contact pads with larger contact area. As shown in FIG. 1, the transfer pads 114 and the electrically corresponding outer pads 113 are inversely designed in pad locations. In the present embodiment, the transfer pads 114 and the outer pads 113 are extruded from the outer surface 112 of the substrate 110, as shown in FIG. 2, to enhance package stacking. Preferably, the outer pads are USB (Universal Serial Bus) pads.

The memory chip 120 is disposed on the inner surface 111 of the substrate 110 and is electrically connected to the outer pads 113 by wire bonding or by flip chip technologies. The memory chip 120 normally is a flash memory. In the present embodiment, a read/write controller chip 141 and a plurality of passive components 142 are further disposed on the inner surface 111 of the substrate 110 where the controller chip 141 is electrically connected to the memory chip 120, the outer pads 113 and the transfer pads 114 to control the read/write of the memory chip 120 and to detect if transfer pads 114 are connected to another package 100 and to transmit control signals to another package 100. The passive components 142 are to protect the read/write controller chip 141 and the memory chip 120 to enhance electrical properties. The encapsulant 130 is formed on the inner surface 111 of the substrate 110 by molding or printing to encapsulate the memory chip 120 and the read/write controller chip 141 and to shape the package 100 as a tiny brick. In different embodiment, the read/write controller chip 141 can be integrated with the memory chip 120 to be a System-on-Chip, SOC.

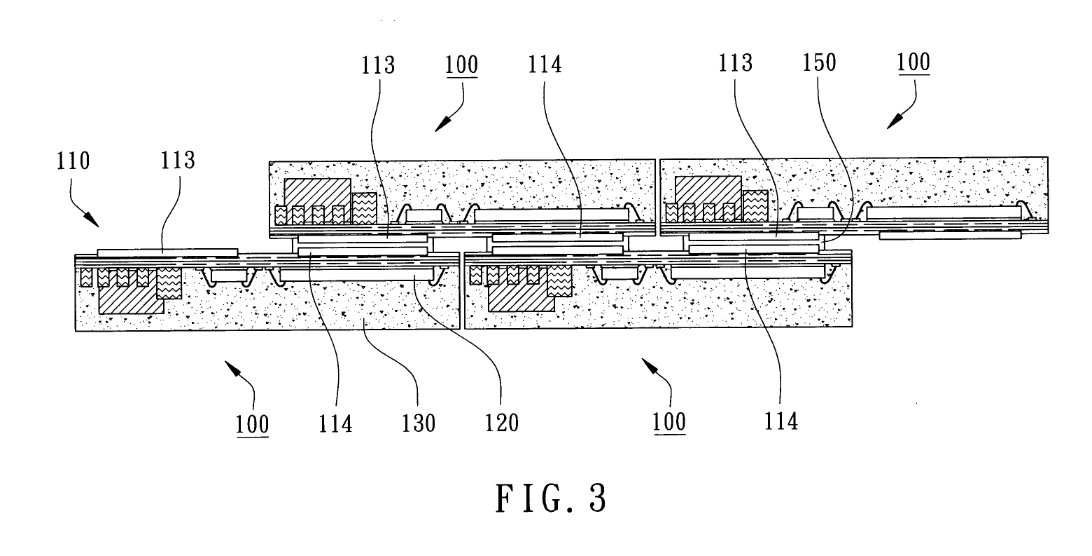

As shown in FIG. 3, a plurality of brick-type semiconductor packages 100 are inversely and horizontally stacked in stagger to be double-layer brick-type semiconductor packages. The transfer pads 114 of the brick-type semiconductor package 100 at a bottom layer can electrically and mechanically connected to the outer pads 114 of another brick-type semiconductor package 100 on a top layer by solder paste 21 or anisotropic conductive film, ACF. Therefore, the overall thickness of the semiconductor package after POP (package-on-package) stacking is kept and is controlled about the thickness of two packages and the number of the horizontally stacked brick-type semiconductor package 100 that can be stacked is not limited and can be expanded according to the requirements of the demanded memory capacities.

As shown in FIG. 1 again, the dimensions of the outer pads 113 can be designed as the same as the ones of the transfer pads 114 to ensure good electrical connections.

Preferably, as shown in FIG. 2, the encapsulant 130 is formed in sawing type after molding so that the encapsulant 130 and the substrate 110 can simultaneously be separated by singulation. A plurality of sidewalls 131 of the encapsulant 130 are aligned with all edges 116 of the substrate 110 so that the encapsulant 130 can fully support the inner surface 111 of the substrate 110 to avoid collapses and deformation of the substrate 110 during usages.

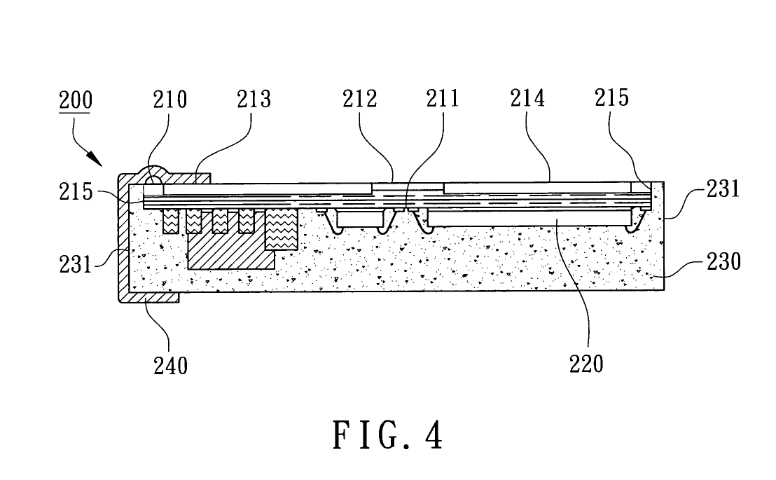

As shown in FIG. 4, according to the second embodiment of the present invention, another brick-type semiconductor package 200 is revealed, primarily comprising a substrate 210, at least a memory chip 220 and an encapsulant 230 where the substrate 210 has an inner surface 211 and an outer surface 212. A plurality of outer pads 213 and a plurality of transfer pads 214 are both formed on the outer surface 212. The memory chip 220 is disposed on the inner surface 211 of the substrate 210 and is electrically connected to the outer pads 213. The encapsulant 230 is formed on the inner surface 211 of the substrate 210 to encapsulate the memory chip 220 and to be shaped like a tiny brick where the transfer pads 214 and the electrically corresponding outer pads 213 are inversely designed in pad locations so that the brick-type semiconductor package 200 can inversely and horizontally stacked in stagger with another brick-type semiconductor package 200. In the present embodiment, a plurality of sides 231 of the encapsulant 230 are slightly larger than and has encapsulated all edges 215 of the substrate 210 so that only the outer surface 212 is exposed to enhance the plugging lifetime of the brick-type semiconductor package 200 and to prevent delamination and degradation of the substrate 210. Preferably, the brick-type semiconductor package 200 further comprises at least a metal clip 240 which locks to one side 231 of the encapsulant 230 and electrically connects to the outer pads 213 to form a plug connector for external connections.

The above description of embodiments of this invention is intended to be illustrative and not limiting. Other embodiments of this invention will be obvious to those skilled in the art in view of the above disclosure.

What is claimed is:

1. A brick-type semiconductor package comprising:
a substrate having an inner surface, an outer surface, a plurality of outer pads and a plurality of transfer pads, wherein both of the outer pads and the transfer pads are formed on the outer surface;
at least a memory chip disposed on the inner surface and electrically connected to the outer pads; and
an encapsulant formed on the inner surface of the substrate to encapsulate the memory chip shaped like a brick;
wherein the transfer pads and the electrically corresponding outer pads are inversely designed in pad locations so that the brick-type semiconductor package can inversely and horizontally stacked in stagger with another brick-type semiconductor package.

2. The brick-type semiconductor package of claim 1, further comprising at least a metal clip locking to one side of the encapsulant and electrically connecting the outer pads for electrical connections.

3. The brick-type semiconductor package of claim 1, wherein a plurality of sides of the encapsulant is aligned with all edges of the substrate.

4. The brick-type semiconductor package of claim 1, wherein a plurality of sides of the encapsulant is slightly larger than all edges of the substrate such that only the outer surface is exposed.

5. The brick-type semiconductor package of claim 1, wherein the outer pads are USB (Universal Serial Bus) pads.

6. The brick-type semiconductor package of claim 1, wherein the dimensions of the outer pads can be designed as the same as the ones of the transfer pads.

7. The brick-type semiconductor package of claim 1, wherein the outer pads and the transfer pads are gold fingers.
